(19) United States
(12) Patent Application Publication
(10) Pub. No.: US 2016/0258059 A1
(43) Pub. Date: Sep. 8, 2016

(54) FLUIDIZED BED ATOMIC LAYER DEPOSITION DEVICE FOR MANUFACTURING NANOCOATING PARTICLES

(71) Applicant: GWANGJU INSTITUTE OF SCIENCE AND TECHNOLOGY, Gwangju (KR)

(72) Inventors: Jaeyoung LEE, Gwangju (KR); Sang Ho CHUNG, Gwangju (KR); Jae Kwang LEE, Gwangju (KR); Hyungkuk JU, Gwangju (KR); Jin Won KIM, Gwangju (KR)

(73) Assignee: GWANGJU INSTITUTE OF SCIENCE AND TECHNOLOGY, Gwangju (KR)

(21) Appl. No.: 14/901,073

(22) PCT Filed: Jul. 15, 2014
(86) PCT No.: PCT/KR2014/006403

§ 371 Date: Apr. 5, 2016

(30) Foreign Application Priority Data
Jul. 15, 2013 (KR) 10-2013-0082895

(51) Int. Cl. C23C 16/44; F04B 37/18; C23C 16/52; F04B 45/053; C23C 16/442; C23C 16/455

(52) U.S. Cl. CPC C23C 16/4417; C23C 16/442; C23C 16/45544; C23C 16/52; F04B 45/0533; F04B 37/18; C23C 16/45555

(57) ABSTRACT

Disclosed is a fluidized bed atomic layer deposition device for manufacturing nanocoating particles. A fluidized bed atomic layer deposition device according to an embodiment of the present invention comprises: a fluidized bed reactor, into which particles to be coated are injected; a reaction material supply unit for supplying reaction gases for coating the particles to be coated into the fluidized bed reactor; and a vibration pump coupled to the fluidized bed reactor such that the reaction gases can move therethrough, the vibration pump giving the reaction gasses regular vibration and thereby forming a turbulence inside the fluidized bed reactor.

### TECHNICAL FIELD

The present invention relates to a fluidized bed atomic layer deposition apparatus for manufacturing nanocoating particles which can deposit a nanoscale layer onto a particle by atomic layer deposition.

### BACKGROUND ART

Atomic layer deposition (ALD) has advantages over chemical vapor deposition (CVD) and physical vapor deposition (PVD), which are typical thin film deposition techniques. Most ALD processes are performed at a low temperature of 400° C. or less and can deposit a thin film on an atomic scale, thereby allowing precise control over film formation. In addition, such an ALD process allows deposition of a thin film having low impurity content and having few or no pinholes.

A typical ALD process has been mainly used in forming a precision thin film for a gate dielectric, a capacitor dielectric, and the like. Recently, there are proposed solutions which are capable of performing nanoscale coating (hereinafter, referred to as “nanocoating”) on various nanostructures having a 3-dimensional structure using fluidized bed atomic layer deposition.

One example of such solutions is as follows. After particles to be coated are introduced into a reactor, a precursor and an inert gas are supplied to the reactor, such that reaction materials are coated onto surfaces of the particles to be coated. Here, the reactor is provided therein with an agitation device such as a stirrer to prevent aggregation of particles to be coated.

However, such solutions have a problem in that particles to be coated are not sufficiently suspended despite the presence of an agitation device. Accordingly, it is difficult to uniformly deposit a film on a surface of the particle and also to achieve the original purpose of preventing aggregation of the particles to be coated.

### DISCLOSURE

### Technical Problem

Embodiments of the present invention provide a fluidized bed atomic layer deposition apparatus which can generate an oscillatory flow of particles to be coated and reaction gases within a reactor using an oscillating pump creating turbulence within the reactor, thereby forming a uniform coating on the particles.

### Technical Solution

In accordance with one aspect of the present invention, a fluidized bed atomic layer deposition apparatus includes: a fluidized bed reactor into which particles to be coated are introduced; a reactant supply unit supplying reaction gases for coating of the particles to be coated into the fluidized bed reactor; and an oscillating pump coupled to the fluidized bed reactor such that the reaction gases can flow therethrough and imparting regular oscillation to the reaction gases to create a turbulence within the fluidized bed reactor.

The oscillating pump may be a diaphragm pump or a membrane pump.

The oscillating pump may include: a diaphragm expanding and contracting to suction or discharge a fluid; a piston mounted on the diaphragm; and an actuator actuating the piston.

The reactant supply unit may include: a first precursor supply unit supplying a first precursor reacting with surfaces of the particles to be coated to be chemically adsorbed onto the particles to be coated; and a second precursor supply unit supplying a second precursor reacting with the first precursor to be chemically adsorbed onto the first precursor.

The apparatus may include an inert gas supply unit supplying an inert gas to the fluidized bed reactor to remove an oversupplied first or second precursor.

The inert gas supply unit may include a flow regulator regulating a flow rate of the inert gas.

The apparatus may further include a vacuum unit maintaining a vacuum within the fluidized bed reactor.

The first precursor supply unit, the second precursor supply unit, and the vacuum unit may be connected to the fluidized bed reactor in parallel.

A gas permeable support selectively allowing only gases to pass therethrough may be disposed at a lower side of the fluidized bed reactor.

### Advantageous Effects

Embodiments of the present invention can provide a fluidized bed atomic layer deposition apparatus which can generate a continuous oscillatory flow of particles to be coated and reaction gases within a fluidized bed reactor using an oscillating pump creating turbulence within the reactor.

Accordingly, the fluidized bed atomic layer deposition apparatus can prevent aggregation of the particles and allows the particles to be better suspended within the reactor such that surfaces of the particles can be more effectively exposed to reaction materials, thereby providing nanoparticles having uniform coatings thereon.

### DESCRIPTION OF DRAWINGS

FIG. 1 is a schematic view of a fluidized bed atomic layer deposition apparatus according to one embodiment of the present invention.

FIG. 2 is a schematic view of one example of an oscillating pump of FIG. 1.

FIG. 3 shows comparison graphs of a pressure profile within a fluidized bed reactor of FIG. 1 vs. a typical pressure profile.

### BEST MODE

Hereinafter, embodiments of the present invention will be described in detail with reference to the accompanying drawings.

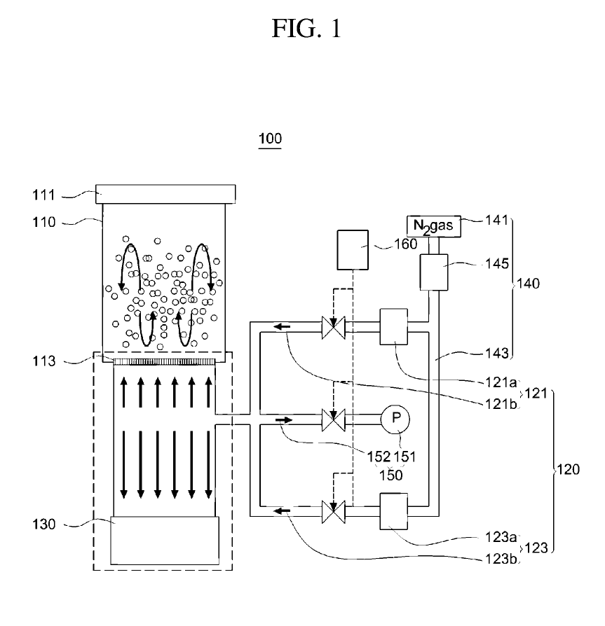

FIG. 1 is a schematic view of a fluidized bed atomic layer deposition apparatus 100 according to one embodiment of the present invention.

The fluidized bed atomic layer deposition apparatus 100 may include a fluidized bed reactor 110, a reactant supply unit 120 supplying reaction gases into the fluidized bed reactor 110, and an oscillating pump 130 coupled to the fluidized bed reactor 110 and creating a turbulence within the fluidized bed reactor 110.

Particles to be coated P are introduced into the fluidized bed reactor 110. Here, the particles to be coated P refer to particles, surfaces of which will be coated. The kind of particles to be coated P is not particularly limited, and the particles to be coated may include, for example, carbon, Pt, Au, Ni, and silica gel particles. The particles to be coated may be nano- to micro-scale particles. The particles to be coated P are suspended within the fluidized bed reactor 110 and have a coating on surfaces thereof through reaction with reaction materials.

The fluidized bed reactor 110 may have any suitable shape without limitation. For example, the fluidized bed reactor may have a cylindrical shape. In addition, the fluidized bed reactor 110 may be formed of any suitable material without limitation. For example, the fluidized bed reactor 110 may be formed of an alloy having corrosion resistance, heat resistance, and thermal conductivity, such as stainless steel.

A reclosable cover 111 may be disposed at an upper side of the fluidized bed reactor 110. The cover 111 may be coupled to the upper side of the fluidized bed reactor 110 through, for example, a hinge.

A gas permeable support 113 may be formed at a lower side of the fluidized bed reactor 110. The gas permeable support 113 serves to support the fluidized bed reactor 110 from below. In addition, the gas permeable support 113 selectively allows only gases to pass therethrough without allowing the particles to pass therethrough. Thus, the particles to be coated P cannot escape from the fluidized bed reactor 110, whereas reaction gases can be supplied into the fluidized bed reactor 110 from the reactant supply unit 120. The gas permeable support 113 may be formed using, for example, a porous membrane. Further, the gas permeable support 113 is regularly replaceable.

The reactant supply unit 120 supplies reaction gases into the fluidized bed reactor 110. Here, the reaction gases refer to materials that react with the particles to be coated P to form coatings on surfaces of the particles to be coated P. The kind of the reaction gases is not limited, and the reaction gases may include, for example, Pt, Pd, TiO₂, Al₂O₃, ZnO, and SiO₂ precursors.

The reactant supply unit 120 may include a plurality of reactant supply units to supply different precursors. For example, the reactant supply unit 120 may include a first precursor supply unit 121 and a second precursor supply unit 123, as shown in FIG. 1. Although the reactant supply unit may include three or more precursor supply units as needed, the present invention will be described herein using an example in which the reactant supply unit includes two precursor supply units 121, 123 for convenience.

The first precursor supply unit 121 supplies a first precursor to be chemically adsorbed onto the particles to be coated P to the fluidized bed reactor 110. The first precursor supply unit 121 may include a first receptacle 121a containing the first precursor and a first supply channel 121a connected from the first receptacle 121a to the fluidized bed reactor 110. The supply channel 121a may be provided with a valve (not shown) for opening/closing the channel.

The second precursor supply unit 123 supplies a second precursor to be chemically adsorbed onto the first precursor to the fluidized bed reactor 110. The second precursor supply unit 123 may include a second receptacle 123a containing the second precursor and a second supply channel 123a connected from the second receptacle 123a to the fluidized bed reactor 110. Similarly to the first supply channel 121a, the second supply channel 123a may be provided with a valve (not shown).

The oscillating pump 130 is coupled to a lower side of the fluidized bed reactor 110. Here, reaction gases supplied from the reactant supply unit 120 flow through the oscillating pump 130. For example, the supply channels 121b, 123b of the reactant supply unit 120 are connected to the oscillating pump 130. Accordingly, reaction gases can be introduced into the oscillating pump 130 and discharged therefrom while being regularly oscillated by the oscillating pump 130.

As described above, the oscillating pump 130 imparts regular oscillation to reaction gases supplied to the fluidized bed reactor 110, thereby creating turbulence within the fluidized bed reactor 110. Thus, the particles to be coated P having been introduced into the fluidized bed reactor 110 can remain suspended within the fluidized bed reactor 110 by the turbulence. This means that the particles to be coated P can be effectively exposed to reaction gases.

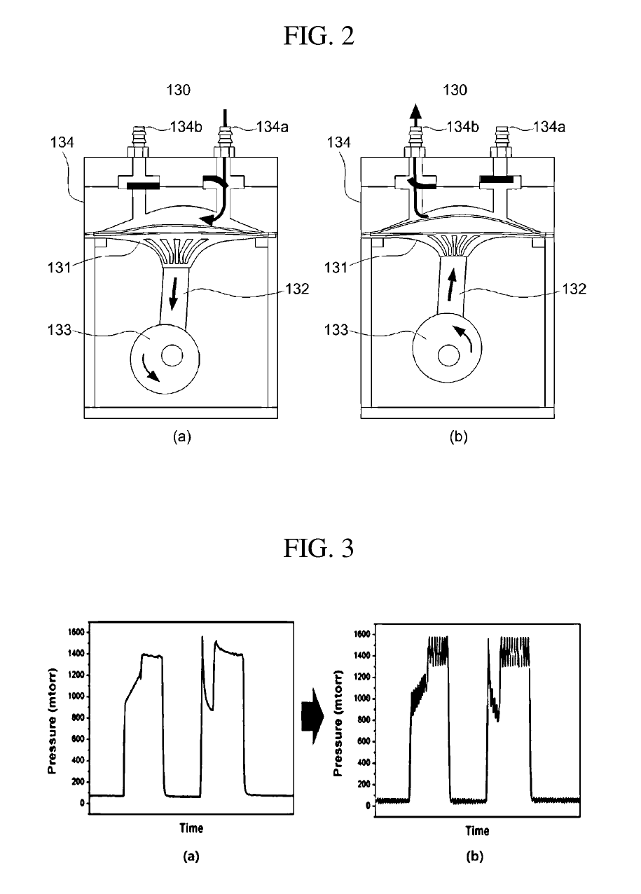

The oscillating pump 130 may be a diaphragm pump or a membrane pump capable of providing oscillation to reaction gases. FIG. 2 is a schematic view of an example of the oscillating pump 130 of FIG. 1. However, it should be understood that the oscillating pump 130 is not limited to ones shown in FIG. 2.

FIG. 2 shows a diaphragm pump as an example of the oscillating pump 130. The oscillating pump 130 includes a diaphragm 131 expanding and contracting to generate suction force and discharge force, a piston 132 mounted on the diaphragm 131, and an actuator 133 actuating the piston 132. These components are placed in a pump chamber 134, and the pump chamber 134 is formed with an inlet through which a fluid is introduced thereinto and an outlet 134b through which the fluid is discharged therefrom. Each of the inlet 134a and the outlet 134b may be provided with a check valve (not shown) to prevent the fluid from flowing backwards.

The actuator 133 is oscillated to cause the piston 132 to reciprocate, thereby changing the internal volume of the pump chamber 134. Such volumetric change of the pump chamber 134 allows the diaphragm 131 to expand and contract, thereby causing a pumping action.

For example, when the piston 132 is moved downward as shown in FIG. 2a, a fluid is introduced into the pump chamber 134, and when the piston 132 is moved upward as shown in FIG. 2b, the fluid is discharged from the pump chamber 134. In addition, such repeated up-and-down movement of the piston 132 can cause the pump to create pressure ripples, thereby imparting oscillation to the fluid.

In the fluidized bed atomic layer deposition apparatus 100 according to the embodiments of the present invention, the oscillating pump 130 configurable as described above imparts oscillation to reaction gases. In other words, reaction gases supplied from the reactant supply unit 120 are oscillated by flowing through the oscillating pump 130. Since oscillated reaction gases are, in turn, supplied to the fluidized bed reactor 110, the particles to be coated P can remain suspended within the fluidized bed reactor 110. Oscillation continues to occur during operation of the oscillating pump 130.

FIG. 3 shows comparison graphs of a pressure profile within the fluidized bed reactor 110 of FIG. 1 vs. a typical pressure profile.

FIG. 3a is a graph showing a pressure profile in a typical reactor, and FIG. 3b is a graph showing a pressure profile within the fluidized bed reactor 110 of FIG. 1. Referring to FIGS. 3a and 3b, it can be seen that the pressure profile of FIG. 3b fluctuates for each period of time. This pressure profile considerably differs from the pressure profile of FIG. 3a that only exhibits increase in pressure with introduction of reaction gases. In other words, it can be seen that turbulence is continuously created within the fluidized bed reactor 110 of FIG. 1.

Referring to FIG. 1 again, the fluidized bed atomic layer deposition apparatus 100 may further include an inert gas supply unit 140 supplying an inert gas to the fluidized bed reactor 110. The inert gas serves to remove the first precursor or the second precursor oversupplied to the fluidized bed reactor 110. This is required for an ALD process, and details thereof will be described below in more detail. The inert gas may be argon (Ar) gas or nitrogen (N₂) gas, without being limited thereto.

The inert gas supply unit 140 may include a third receptacle 141 containing the inert gas and a third supply channel 143 extending from the third receptacle 141. The third supply channel 143 may be provided with a valve (not shown) for opening/closing the channel.

The third supply channel 143 may extend from the third receptacle 141 to the first and second receptacles 121a, 123a of the reactant supply unit 120. That is, the third supply channel 143 may be connected to the first and second supply channels 121b, 123b. In this case, the inert gas may be supplied to the fluidized bed reactor 110 through the third supply channel 143 and the first and second supply channels 121b, 123b.

The inert gas supply unit 140 may further include a flow regulator 145 regulating the flow rate of the inert gas. The flow regulator 145 is a mass flow controller (MFC) generally used in the art and serves to regulate the flow rate of the inert gas.

The fluidized bed atomic layer deposition apparatus 100 may further include a vacuum unit 150 for maintaining a vacuum within the fluidized bed reactor 110. The vacuum unit 150 may include a vacuum pump 151 for maintaining a vacuum within the fluidized bed reactor 110 and a vacuum line 152 connecting the vacuum pump 151 to the fluidized bed reactor 110.

The first precursor supply unit 121, the second precursor supply unit 123, and the vacuum unit 150 may be connected in parallel to one another. In other words, the first supply channel 121b, the second supply channel 123b, and the vacuum line 152 may be disposed in parallel and joined into one line at the fluidized bed reactor 110 side, if necessary.

The fluidized bed atomic layer deposition apparatus 100 may further include a controller 160 controlling the entire apparatus. The controller 160 may control, for example, opening/closing of the cover 111 of the fluidized bed reactor 110, the amount of reaction gases supplied from the reactant supply unit 120, the order in which reaction gases are supplied, and the like (for example, by controlling opening/closing of the valves provided to the supply channels). In addition, the controller may control actuation of the vacuum pump 130, regulation of the flow rate of the inert gas supplied from the inert gas supply unit 140, and actuation of the vacuum unit 150. The controller 160 may be connected to the components of the fluidized bed atomic layer deposition apparatus 100 by wire or wirelessly and sends control signals to the components, thereby controlling the components.

Next, operation of the fluidized bed atomic layer deposition apparatus 100 will be described.

In the fluidized bed atomic layer deposition apparatus 100, particles to be coated P introduced into the fluidized bed reactor 110 are coated through an ALD process. The temperature of the fluidized bed reactor 110 may be maintained in a temperature range not causing decomposition of supplied reaction gases (precursors).

After the particles to be coated P are introduced into the fluidized bed reactor 110, the first precursor supply unit 121 supplies a first precursor to the fluidized bed reactor 110. The first precursor may be supplied under the control of the controller 160. Here, the second precursor supply unit 123 and the inert gas supply unit 140 do not operate.

The reaction gas (first precursor) from the first precursor supply unit 121 is supplied to the fluidized bed reactor 110 through the oscillating pump 130 and reacts with surfaces of the particles to be coated P to be chemically adsorbed thereto. The oscillating pump 130 continues to impart oscillation to the reaction gas such that the particles to be coated P can remain suspended within the fluidized bed reactor 110. Thus, the particles to be coated P can more effectively react with the reaction gas.

Once the first precursor is deposited onto the surfaces of the particles to be coated P, additional reaction gases do not react anymore (self-limiting reaction). Unreacted excess reaction gases are removed by the inert gas. The inert gas may be supplied from the inert gas supply unit 140 under the control of the controller 160.

After the excess reaction gases are completely removed, the second precursor supply unit 123 supplies a second precursor to the fluidized bed reactor 110. The second precursor may be supplied under the control of the controller 160. Here, the first precursor supply unit 121 and the inert gas supply unit 140 do not operate.

The reaction gas (second precursor) from the second precursor supply unit 123 is supplied to the fluidized bed reactor 110 through the oscillating pump 130 and chemically adsorbed onto the first precursor deposited on the surfaces of the particles to be coated P. The oscillating pump 130 continues to impart oscillation to the reaction gas such that the particles to be coated P can remain suspended within the fluidized bed reactor 110. Thus, the first precursor on the surfaces of the particles to be coated P can more effectively react with the reaction gas (second precursor).

Once the second precursor is adsorbed onto the surface of the first precursor, additional reaction gases do not react anymore. Unreacted excess reaction gases are removed by the inert gas. The inert gas may be supplied from the inert gas supply unit 140 under the control of the controller 160.

The above processes may form one cycle and films can be coated onto the surfaces of the particles to be coated P to a desired thickness by repeating the cycle.

As described above, embodiments of the present invention can generate oscillatory flow of particles to be coated and reaction gases within a fluidized bed reactor using an oscillating pump creating turbulence within the reactor. Thus, the embodiments of the present invention can prevent aggregation of the particles to be coated and allows the particles to be better suspended within the reactor such that surfaces of the particles to be coated can be more effectively exposed to reaction materials, thereby manufacturing nanoparticles having uniform coatings thereon.

Although some embodiments have been described herein, it should be understood that these embodiments are provided for illustration only and are not to be construed in any way as limiting the present invention, and that various modifications, changes, alterations, and equivalent embodiments can be made by those skilled in the art without departing from the spirit and scope of the invention.

### LIST OF REFERENCE NUMERALS

P: Particles to be coated
100: Fluidized bed atomic layer deposition apparatus
110: Fluidized bed reactor
111: Cover
113: Gas permeable support
120: Reactant supply unit
121: First precursor supply unit
121a: First receptacle
123: Second precursor supply unit
123a: Second receptacle
123b: Second supply channel
130: Oscillating pump
131: Diaphragm
132: Piston
133: Actuator
134: Pump chamber
134a: Inlet
134b: Outlet
140: Inert gas supply unit
141: Third receptacle
143: Third supply channel
145: Flow regulator
150: Vacuum unit
151: Vacuum pump
152: Vacuum line
160: Controller

1. A fluidized bed atomic layer deposition apparatus, comprising:
a fluidized bed reactor into which particles to be coated are introduced;
a reactant supply unit supplying reaction gases for coating of the particles to be coated into the fluidized bed reactor; and
an oscillating pump coupled to the fluidized bed reactor such that the reaction gases can flow therethrough and imparting regular oscillation to the reaction gases to create a turbulence within the fluidized bed reactor.

2. The fluidized bed atomic layer deposition apparatus according to claim 1, wherein the oscillating pump is a diaphragm pump or a membrane pump.

3. The fluidized bed atomic layer deposition apparatus according to claim 2, wherein the oscillating pump comprises: a diaphragm expanding and contracting to suction or discharge a fluid; a piston mounted on the diaphragm; and an actuator actuating the piston.

4. The fluidized bed atomic layer deposition apparatus according to claim 1, wherein the reactant supply unit comprises: a first precursor supply unit supplying a first precursor reacting with surfaces of the particles to be coated to be chemically adsorbed onto the particles to be coated; and a second precursor supply unit supplying a second precursor reacting with the first precursor to be chemically adsorbed onto the first precursor.

5. The fluidized bed atomic layer deposition apparatus according to claim 4, comprising: an inert gas supply unit supplying an inert gas to the fluidized bed reactor to remove an oversupplied first or second precursor.

6. The fluidized bed atomic layer deposition apparatus according to claim 5, wherein the inert gas supply unit comprises a flow regulator regulating a flow rate of the inert gas.

7. The fluidized bed atomic layer deposition apparatus according to claim 4, further comprising: a vacuum unit maintaining a vacuum within the fluidized bed reactor.

8. The fluidized bed atomic layer deposition apparatus according to claim 7, wherein the first precursor supply unit, the second precursor supply unit, and the vacuum unit are connected to the fluidized bed reactor in parallel.

9. The fluidized bed atomic layer deposition apparatus according to claim 1, wherein a gas permeable support selectively allowing only gases to pass therethrough is disposed at a lower side of the fluidized bed reactor.
